(19) United States
(12) Patent Application Publication
(10) Pub. No.: US 2024/0006852 A1
(43) Pub. Date: Jan. 4, 2024

(54) LASER EMITTER, LIGHT SOURCE ASSEMBLY, AND LASER RADAR

(71) Applicant: HESAI TECHNOLOGY CO., LTD., Shanghai (CN)

(72) Inventors: Jiarui FEI, Shanghai (CN); Chenren YU, Shanghai (CN); Jianfeng LIU, Shanghai (CN); Shaoqing XIANG, Shanghai (CN)

(73) Assignee: HESAI TECHNOLOGY CO., LTD., Shanghai (CN)

(21) Appl. No.: 18/466,863

(22) Filed: Sep. 14, 2023

Related U.S. Application Data
(63) Continuation of application No. PCT/CN2021/138310, filed on Dec. 15, 2021.

(30) Foreign Application Priority Data
Mar. 17, 2021 (CN) 202110285338.6

(51) Int. Cl. H01S 5/183; H01S 3/08; H01S 5/42; H01S 5/026; G01S 17/88

(52) U.S. Cl. CPC H01S 5/18366; H01S 3/08059; H01S 5/423; H01S 5/026; G01S 17/88

(57) ABSTRACT

A laser device, a light source module and a laser radar. The laser device comprises: a light-emitting lamination, comprising a first reflector (105), an active region (104) and a second reflector (102), which are sequentially arranged in a light emergence direction, wherein the light-emitting lamination comprises one or more light-emitting units (200), and each of the light-emitting units (200) comprises a plurality of regularly arranged light-emitting points (203); and electrode units (107) located on the side of the first reflector (105) that is away from the active region (104), wherein each of the electrode units (107) corresponds to one light-emitting unit (200) and is used for loading a driving signal to the light-emitting unit (200). The laser device can improve the uniformity of luminous intensity.

### TECHNICAL FIELD

The present disclosure relates to the field of laser detection, and in particular, to a laser emitter, a light source assembly, and a laser radar.

### BACKGROUND

A Light Detection and Ranging (LIDAR) performs important tasks such as roadside detection, obstacle recognition, and simultaneous localization and mapping (SLAM) in automatic driving.

Specifically, a LIDAR system includes a laser emitting system and a light receiving system. The laser emitting system includes a light emitting unit configured to generate an emitted light pulse. The emitted light pulse is incident on a target object and reflected to generate an echo beam, and finally the echo beam is received by the light receiving system. The receiving system accurately measures a propagation time between emission and reflection of the incident light pulse. Since the light pulse is propagated at a speed of light, and the speed of light is known, the propagation time can be converted into a measured distance.

The LIDAR can accurately measure a position (a distance and an angle), a motion state (a speed, vibration, and a posture), and a shape of a target, to detect, identify, distinguish, and track the target. Due to the advantages such as a fast measurement speed, high accuracy, and a long measurement range, the laser radar has been widely used in an unmanned vehicle.

The light emitting unit of the laser radar in the prior art has the problem of nonuniform luminous intensity.

### SUMMARY

The present disclosure provides a laser emitter, a light source assembly, and a laser radar, to improve the uniformity of luminous intensity.

The present disclosure provides a laser emitter, wherein the laser emitter includes: a light-emitting stack, including a first reflector, an active region, and a second reflector sequentially arranged in a light emission direction; where the light-emitting stack includes one or more light-emitting units, and each of the light-emitting units includes a plurality of regularly arranged light-emitting points; and electrode units, located on a side of the first reflector away from the active region, where each of the electrode units corresponds to one of the light-emitting units and is configured to load a drive signal to the light-emitting unit.

Optionally, the electrode unit includes two drive ends configured to load the drive signal to the light-emitting unit. The drive ends are arranged at two ends of the electrode unit in a direction of extension, each of the drive ends is provided with a bonding pad, and the bonding pad is configured to load the drive signal.

Optionally, the laser emitter further includes an insulating layer located on a side of the first reflector away from the active region, where the insulating layer is configured to cover the electrode units and isolate adjacent electrode units.

Optionally, the electrode unit includes a plurality of drive ends configured to load the drive signal to the light-emitting unit. Each of the drive ends is provided with a solder ball, an opening is provided at a position of the insulating layer corresponding to the solder ball, the solder ball protrudes from a surface of the insulating layer through the opening, and the solder ball is configured to load the drive signal.

Optionally, the solder balls are uniformly arranged in the direction of extension of the electrode unit.

Optionally, the solder balls of the adjacent electrode units are staggered in the direction of the extension of the electrode unit.

Optionally, the light-emitting stack further includes a substrate, and the substrate is located on a side of the second reflector away from the active region. Each of the light-emitting points includes: a first contact electrode, located on a side of the first reflector away from the active region; and a second contact electrode, located on a side of the substrate away from the active region.

Optionally, the second contact electrode forms a light transmitting hole.

Optionally, each of the light-emitting points includes: a first contact electrode, located on a side of the first reflector away from the active region; and a second contact electrode, located on a side of the second reflector toward the active region.

Optionally, a plurality of first contact electrodes of the same light-emitting unit are connected to the corresponding electrode units; and the second contact electrodes of the light-emitting points in the laser emitter are connected.

Optionally, the light-emitting stack has a microlens structure on a light emission surface.

Optionally, the laser emitter is a vertical-cavity surface-emitting laser (VCSEL), and the first reflector and the second reflector are distributed Bragg reflectors (DBR).

Optionally, the laser emitter is a back side illumination laser emitter.

In order to resolve the technical problem, the present disclosure further provides a light source assembly, including a laser emitter and a driving board, where the laser emitter is the laser emitter provided in the embodiment of the present disclosure. The driving board includes: a drive circuit, configured to provide a drive signal; and a first bonding pad, configured to be electrically connected to the electrode unit and provide the drive signal to the electrode unit.

Optionally, the driving board further includes: a second bonding pad, configured to provide signals with different electrical properties to the laser emitter.

Optionally, the second bonding pad is an annular bonding pad surrounding the electrode unit.

In order to resolve the technical problem, the present disclosure further provides a laser radar, including an emitting module and a receiving module. The emitting module includes the light source assembly provided in the embodiment of the present disclosure and is configured to transmit a detection beam. The receiving module includes one or more photodetectors, and is configured to receive an echo beam of the detection beam reflected by a target object and convert the echo beam to an electrical signal.

Compared with the conventional technologies, the technical solutions of the present disclosure have the following advantages.

In the present disclosure, the electrode unit is located on the side of the first reflector away from the active region, that is, the electrode unit is not located in the direction of light emission, so that the light emission surface and the electrode unit are respectively located on different sides of the laser emitter. In this way, the electrode unit does not need to be provided with an opening for emitting light, so that the electrode unit has a relatively large effective width, thereby reducing parasitic parameters such as a parasitic resistance and a parasitic inductance, further improving the capability of transmitting the drive signal by the electrode unit and improving the uniformity of luminous intensity of the laser emitter.

### BRIEF DESCRIPTION OF THE DRAWINGS

FIG. 1 is a top view of a laser emitter according to the conventional technologies.

FIG. 2 is a circuit diagram of a light-emitting unit in the laser emitter of FIG. 1.

FIG. 3 is a brightness distribution diagram of a plurality of light-emitting points taken along line of OO′ in the light-emitting unit in FIG. 1.

FIG. 4 is a schematic side view of another laser emitter according to the conventional technologies.

FIG. 5 is a top view of the laser emitter in FIG. 4.

FIG. 6 is a schematic side view of a laser emitter according to a first embodiment of the present disclosure.

FIG. 7 is a top view of an array arrangement of the laser emitter shown in FIG. 6.

FIG. 8 is a side view of the laser emitter according to a second embodiment of the present disclosure.

FIG. 9 is a top view of the laser emitter shown in FIG. 8.

FIG. 10 is a side view of a laser emitter according to a third embodiment of the present disclosure.

FIG. 11 is a top view of the laser emitter shown in FIG. 10.

### DETAILED DESCRIPTION

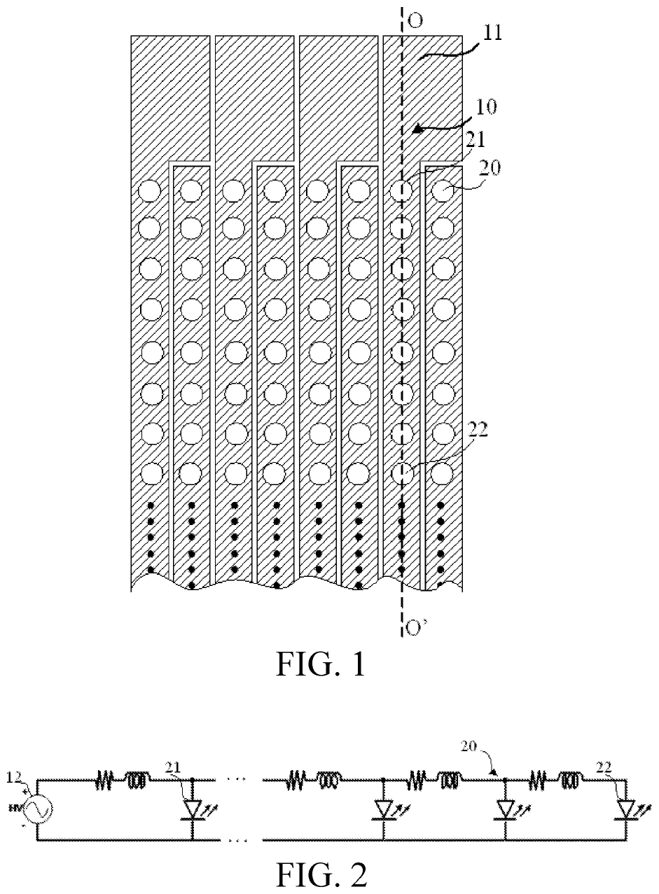

As described in the background, the light emitting unit in the conventional technologies has the problem of nonuniform luminous intensity. The causes of the problem are analyzed below. With reference to FIG. 1 and FIG. 2, a top view of a laser emitter and a circuit diagram of a light-emitting unit according to the conventional technologies are shown respectively. The laser emitter is an area array laser emitter, including a plurality of light-emitting points 20 arranged in an array, so that the light emitted by the area array laser can cover a relatively large field of view, thereby improving the detection efficiency of a laser radar. In order to make the plurality of light-emitting points 20 arranged in a two-dimensional array in the area array laser emitter have higher luminous power simultaneously, the conventional technologies usually adopt a column addressing structure to drive each column of light-emitting points 20 to emit light separately, so that the plurality of light-emitting points 20 located in the same column form a light-emitting unit 10, and the light-emitting unit 10 has an elongated structure extending in a column direction.

The laser emitter is externally connected to a drive circuit 12, which provides a drive signal to each of the light-emitting units 10. The plurality of light-emitting points 20 located in the same light-emitting unit 10 are connected in parallel, and can be driven to emit light while the drive circuit 12 provides the drive signal. Specifically, the drive circuit 12 loads the drive signal to the light-emitting unit 10 through a bonding pad 11 located at the column end, since an interconnect metal layer shared by the plurality of light-emitting points in the light-emitting unit 10 is elongated and has the characteristics of a large length and a small width. The drive circuit 12 loads a high-current and high-frequency drive signal to the metal layer through the bonding pad at the end of the elongated interconnect metal layer. Since a length-width ratio of the interconnect metal layer is relatively large, it is easy to produce resistance and parasitic capacitance, which causes a bias voltage on the light-emitting point to gradually decrease as the light-emitting point is away from the bonding pad 11, therefore, the brightness also gradually decreases.

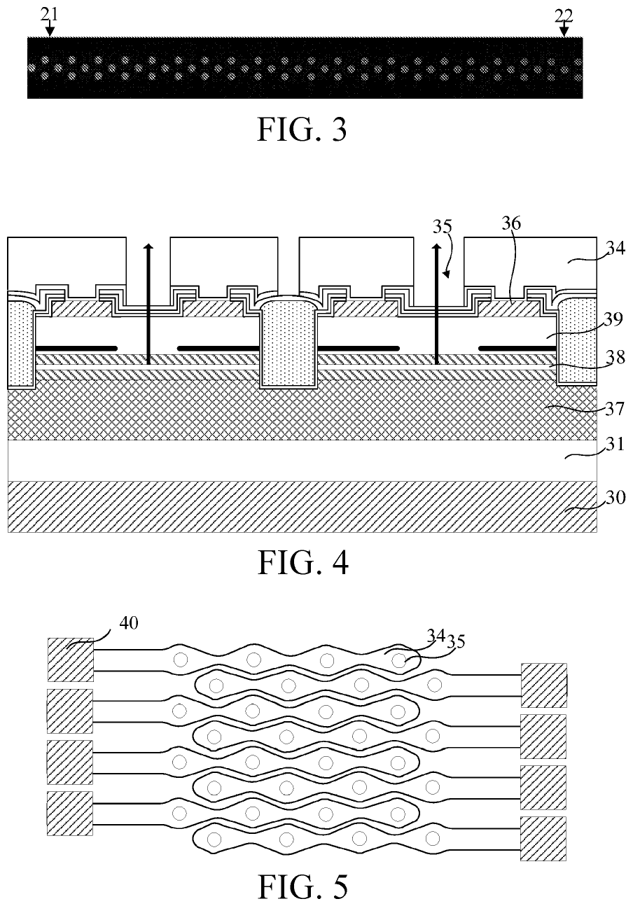

FIG. 3 shows the brightness distribution of the plurality of light-emitting points in an OO′ direction in the light-emitting unit, in which the brightness of the light-emitting point 21 near the bonding pad 11 is significantly greater than that of the light-emitting point 22 away from the bonding pad 11. Therefore, the laser emitter has the problem of nonuniform luminous intensity.

Referring to FIG. 4, FIG. 4 shows a schematic side view of another laser emitter according to the conventional technologies. The laser emitter is a vertical-cavity surface-emitting laser (VCSEL) front side illumination area array laser emitter, including: a substrate 31, a light-emitting stack (including a first reflector 37, an active region 38, and a second reflector 39 sequentially arranged in a light emission direction) located on the substrate 31, where a back side of the substrate 31 is covered with a cathode contact metal 30, and an anode contact metal 36 is formed on the light-emitting stack, and an interconnect metal layer 34 located on the anode contact metal 36. An opening 35 is formed in the interconnect metal layer 34 configured to allow light emitted by the light-emitting stack to be emitted.

With reference to the top view of the interconnect metal layer 34 shown in FIG. 5, since the opening 35 is formed in the interconnect metal layer 34, the effective width of the interconnect metal layer 34 used for allowing the current to pass through is further reduced, so that parasitic parameters such as resistance and parasitic inductance are further increased, and the transmission ability of a high-frequency drive signal from a bonding pad 40 to the far end is further reduced, which intensifies the problem of uniform luminous intensity of the laser emitter.

In order to resolve the above technical problem, an embodiment of the present disclosure provides a laser emitter, including: a light-emitting stack, including a first reflector, an active region, and a second reflector sequentially arranged in a light emission direction, where the light-emitting stack includes one or more light-emitting units, and each of the light-emitting units includes a plurality of regularly arranged light-emitting points; and electrode units, located on a side of the first reflector away from the active region, where each of the electrode units corresponds to one light-emitting unit and is configured to load a drive signal to the light-emitting unit through a drive end. In the embodiment of the present disclosure, the electrode unit is located on the side of the first reflector away from the active region, that is, the electrode unit is not located in the light emission direction, so that the light emission surface and the electrode unit are respectively located on different sides of the laser emitter. In this way, the electrode unit does not need to be provided with an opening for emitting light, so that the electrode unit has a relatively large effective width, thereby reducing parasitic parameters such as a parasitic resistance and a parasitic inductance, further improving the transmission capacity of the drive signal and improving the uniformity of luminous intensity of the laser emitter.

In order to make the foregoing objectives, features, and advantages of the present disclosure more apparent and easier to understand, specific embodiments of the present disclosure are described in detail below with reference to the accompanying drawings.

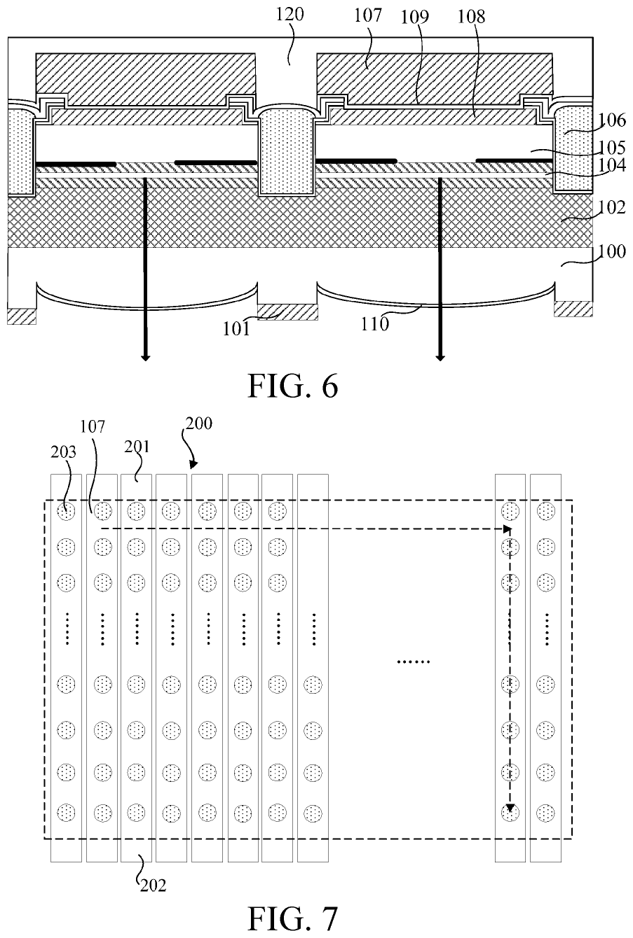

Referring to FIG. 6 and FIG. 7, FIG. 6 and FIG. 7 show side and top views of a laser emitter according to a first embodiment of the present disclosure. In this embodiment, the laser emitter is an area array laser emitter. More specifically, a VCSEL is used as an example for description herein.

The laser emitter includes:

a substrate 100 configured to provide a process operation platform.

In this embodiment, the substrate 100 may further be used as a basis for formation of microlenses, and therefore a material of the substrate 100 may further be a material suitable for process needs or easy integration.

In this embodiment, the material of the substrate 100 is gallium arsenide. In other embodiments, the material of the substrate may further be other III/V compounds such as gallium nitride and silicon.

Specifically, the substrate 100 is made of N-doped gallium arsenide.

The light-emitting stack includes a first reflector 105, an active region 104, and a second reflector 102 sequentially arranged in a light emission direction.

In this embodiment, the light emission direction is the direction from top to bottom in the figure (the direction indicated by the arrow in the figure). Therefore, the second reflector 102, the active region 104, and the first reflector 105 are sequentially located on the substrate 100. The active region 104 is used to radiate photons, the first reflector 105 and the second reflector 102 form a resonator configured to cause the radiated photons to form coherent oscillation, strong enough injection currents can cause the photons to overcome various losses of the device itself to form lasing, and then the laser is emitted from the reflector as an emitting mirror. Generally, light emitted by the VCSEL is located in the near-infrared band.

In this embodiment, the second reflector 102 is a distributed Bragg reflector (DBR). The DBR is a multilayer structure, which is formed by alternating two optical films with different refractive indices. Fresnel reflection occurs at each interface of the two optical films. At an operating wavelength, an optical path difference of reflected light at two adjacent interfaces is half a wavelength, and in addition, the reflection at the interface also causes the optical path difference of half a wavelength. Therefore, all of the reflected light of the operating wavelength at the interface is coherently enhanced.

It should be noted that, the reflectivity of two DBRs should be different. The DBR on one side has a reflectivity approximating 100%, and may be used as a total reflector of a resonator, and the DBR on the other side has a lower reflectivity, and may be used as an emitting mirror of the resonator. In this embodiment, the light emission direction of the laser emitter is from top to bottom, and therefore the second reflector 102 is a light emitting mirror and adopts an N-type DBR.

The distributed Bragg reflector is formed by alternating two optical films with different refractive indices, such as AlₓGa₁₋ₓAs/Al_{1-y}Ga_{y}As, where values of x and y may be different.

In addition, an optical path of each optical film is λ/4, where λ is the operating wavelength of the laser emitter.

In the active region 104, the basis for realizing the inversion distribution of internal carriers is established through a multi-quantum well structure to radiate photons.

For example, the active region 104 includes gallium indium arsenide (GalnAs)/gallium arsenide (GaAs) quantum well.

The first reflector 105 is configured to match the second reflector 102 to form a resonator. In order to cause the emitted light of the laser emitter to be emitted from top to bottom, the first reflector 105 is a total reflector. Specifically, the first reflector 105 is also a distributed Bragg reflector formed by alternating two optical films with different refractive indices, such as AlₓGa₁₋ₓAs/Al_{1-y}Ga_{y}As, where values of x and y may be different. In addition, an optical path of each optical film is λ/4, where λ is the operating wavelength of the laser emitter.

It should be noted that, in other embodiments, the first reflector 105 and the second reflector 102 may also be made of other dielectric materials. Specifically, the first reflector and the second reflector are formed by stacks of a material with high refractive index and a material with low refractive index. The materials with high refractive index such as tantalum pentoxide, hafnium oxide, titanium dioxide and the like may be used. The materials with low refractive index such as magnesium fluoride and silicon dioxide may be used.

It should be noted that, the first reflector 105 and the second reflector 102 are doped to reduce the resistance thereof. Specifically, the first reflector 105 and the second reflector 102 have different types of doping. The second reflector 102 has the same type of doping as the substrate 100.

Referring to FIG. 6 and FIG. 7, the first reflector 105, the active region 104, and a part of the second reflector 102 are separated into different regions by a separation structure 106, thereby forming different light-emitting points 203. As shown in FIG. 7, the VCSEL is an area array laser emitter and includes a plurality of light-emitting points 203. When the laser emitter emits light, the drive signal is loaded to the active region 104 through the drive circuit to realize photon radiation, thereby forming the light-emitting point 203. In this embodiment, the light-emitting point 203 further includes:

a first contact electrode 108, located on a side of the first reflector 105 away from the active region 104; and a second contact electrode 101, located on a side of the substrate 100 away from the active region 104.

The first contact electrode 108 herein is an anode contact metal layer configured to be connected to a positive electrode of the drive circuit, and the second contact electrode 101 is a cathode contact electrode configured to be connected to a negative electrode of the drive circuit.

In this embodiment, the laser emitter emits light from the position of the substrate 100, and a light transmitting hole is formed in the second contact electrode 101.

The laser emitter further includes electrode units 107 located on a side of the first reflector 105 away from the active region 104. Each of the electrode units 107 corresponds to one light-emitting unit 200 and is configured to load the drive signal to the light-emitting unit 200.

The light emission direction of the laser emitter in the embodiment of the present disclosure is a direction from the active region 104 to the second reflector 102 (from top to bottom, as shown by the arrow in FIG. 6), and the electrode unit 107 is located on the side of the first reflector 105 away from the active region 104. Therefore, the electrode unit 107 does not need to be provided with a light transmitting hole, thereby ensuring the integrity of the material of the electrode unit 107 and reducing the inductance and parasitic capacitance of the electrode unit 107. Therefore, the electrode unit 107 has a relatively large effective width, thereby reducing parasitic parameters such as a parasitic resistance and a parasitic inductance, further improving the transmission capacity of the drive signal and improving the uniformity of luminous intensity of the laser emitter.

As shown in FIG. 6, in this embodiment, the electrode unit 107 is located above the first contact electrode 108 and is electrically connected to the first contact electrode 108. Specifically, the electrode unit 107 is configured to realize the electrical connection between the drive circuit and the light-emitting point and transmit the drive signal of an external circuit to the first contact electrode 108.

In this embodiment, a contact layer 109 is further formed between the electrode unit 107 and the first contact electrode 108 to reduce the contact resistance between the electrode unit 107 and the first contact electrode 108.

FIG. 7 is a top view of an array arrangement of the laser emitter shown in FIG. 6.

The light-emitting point 203 illustrates light emission positions formed by the second contact electrode 101 shown in FIG. 6. In this embodiment, a plurality of light-emitting points 203 are arranged in a matrix array, and a column of light-emitting points 203 forms a light-emitting unit 200. A plurality of first contact electrodes 108 of the same light-emitting unit 200 are connected to corresponding electrode units 107, and correspondingly, the electrode units 107 are a column of strip-shaped electrodes. In addition, in this embodiment, the second contact electrode 101 of the light-emitting point 203 of the laser emitter are connected. In other embodiments, the light-emitting point 203 may further be arranged in a honeycomb pattern.

In this embodiment, since a light emission surface of the light-emitting point 203 is the substrate 100, and the electrode unit 107 is located on the other side of the light emission surface of the light-emitting stack, the electrode unit 107 may be made of an opaque material. Specifically, the electrode unit 107 is an interconnect metal layer. The interconnect metal layer may be made of metal materials such as copper and aluminum.

The laser emitter in the embodiment of the present disclosure includes a plurality of columns of strip-shaped electrodes, and adjacent strip-shaped electrodes are insulated by an insulating layer 120.

The insulating layer 120 may be made of silicon oxide, silicon nitride, silicon oxynitride, and the like. These materials are commonly used for insulating materials in semiconductor technology and have relatively low dielectric constants, so that the parasitic capacitance can be reduced.

Still referring to FIG. 6, the light emission direction of the laser emitter in the embodiment of the present disclosure is a direction from the active region 104 to the second reflector 102. The light formed by the light-emitting stack emit through the substrate 100, that is, the side of the substrate 100 away from the second reflector 102 is the light emission surface, and a side of the substrate 100 realizing light emission is defined as a back side of the substrate. In the embodiment of the present disclosure, a microlens structure 110 is further formed on the back side of the substrate, which is configured to converge the light formed by the light-emitting stack.

Specifically, a convex surface with a certain curvature is formed at a position on the back side of the substrate 100 corresponding to each light-emitting point, and the convex surface constitutes the microlens structure 110.

It should be noted that, the second contact electrode 101 is located on the back side of the substrate between the microlens structures 110. In this embodiment, the second contact electrode 101 of the light-emitting point of the laser emitter is connected. Accordingly, the second contact electrode 101 is a metal layer located on the back side of the substrate, and the metal layer has a light transmitting hole formed at the position of the microlens structure.

Still referring to FIG. 7, the electrode unit 107 includes two drive ends configured to load a drive signal to the light-emitting unit.

The drive end herein is a connecting end of the electrode unit 107 electrically connected to the drive circuit. The drive ends are arranged on two ends of the electrode unit in a direction of extension, so as to reduce the transmission distance of the drive signal.

In this embodiment, the electrode unit 107 is a strip-shaped electrode, and two ends of the strip-shaped electrode are drive ends 201 and drive end 202. Correspondingly, the two drive ends 201 and drive end 202 cooperate and simultaneously load the drive signal to the light-emitting unit 200, so that the light-emitting point 203 of the light-emitting unit 200 emits light. Compared with the solution that only one drive end is arranged for each column of light-emitting points in the conventional technologies, in the embodiment of the present disclosure, each light-emitting unit 200 is connected to two drive ends 201 and 202. A distance between the light-emitting point and the drive end is shortened, which can reduce the transmission distance of the drive signal from the drive circuit to the light-emitting point 203, thereby reducing the problem of weakening of the drive signal caused by the parasitic capacitance and the resistance, and further improving the light uniformity of the laser emitter.

Specifically, the drive ends 201 and 202 are each provided with a bonding pad, and the bonding pad is configured to be connected to the drive circuit to load the drive signal. In other embodiments, the drive ends may further be electrically connected to the drive circuit through solder balls, wire bonding, and the like.

It should be noted that, in other embodiments, each electrode unit 107 may alternatively be provided with only one drive end. In the embodiment of the present disclosure, the light emission surface and the electrical connection are respectively arranged on different sides of the laser emitter, so that the purpose of improving the light emission uniformity can be achieved.

Preferably, a plurality of drive ends (for example, three or more) are arranged on the electrode unit, and the drive signal is simultaneously loaded by the drive ends, so that electric energy can be injected into the light-emitting unit through a plurality of positions, thereby further shortening the transmission distance of the drive signal, further reducing the parasitic capacitance and resistance, and alleviating the problem of nonuniform light emitting.

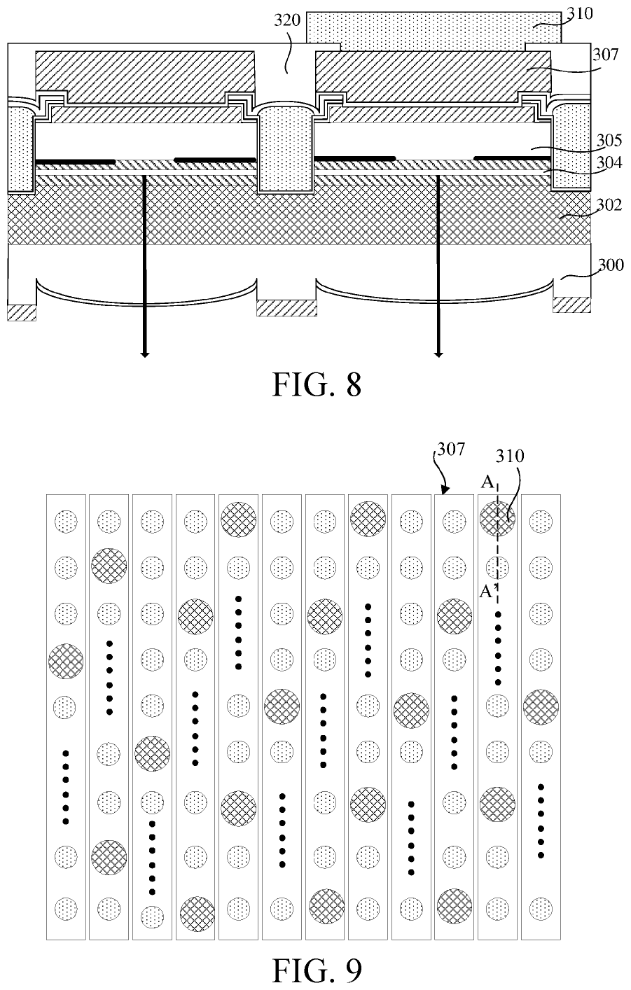

Referring to FIG. 8 and FIG. 9, FIG. 8 and FIG. 9 show a side view and a top view of a laser emitter according to a second embodiment of the present disclosure. For the similarity between this embodiment and the first embodiment, details are not described again. A difference between this embodiment and the first embodiment lies in that:

the laser emitter further includes an insulating layer 320 located on a side of a first reflector 305 away from an active region 304. The insulating layer 320 is configured to cover electrode units 307 and isolate adjacent electrode units 307.

The insulating layer 320 is configured to achieve insulation between adjacent electrode units 307 and further configured to achieve insulation between drive ends.

The insulating layer 320 is made of a dielectric material with a low dielectric constant, for example, silicon oxide, silicon nitride, silicon oxynitride, and the like, so that the parasitic capacitance can be reduced. These materials are dielectric materials commonly used in semiconductor technology, and have good process compatibility.

Each of the electrode units 307 includes a plurality of drive ends configured to load a drive signal to the light-emitting unit 311. Each of the drive ends electrically connects the electrode unit 307 to the drive circuit through conductive elements.

In this embodiment, the conductive elements are solder balls, as shown in FIG. 9. Each of the drive ends is provided with a solder ball 310, and an opening is provided at a position of the insulating layer 320 corresponding to the solder ball 310. The solder ball 310 is filled in the opening and protrudes from the surface of the insulating layer 320, and the solder ball 310 is configured to load the drive signal.

Specifically, the solder ball 310 is connected to the electrode unit 307 exposed from the opening. A plurality of solder balls 310 are arranged in sequence on a column of electrode units 307, which can further reduce the transmission distance of the drive signal from the drive circuit to the electrode unit 307, thereby reducing the parasitic resistance and capacitance.

Compared with the solution that the drive ends are arranged at the ends of the electrode units 307, in the embodiment of the present disclosure, the positions at which a column of drive ends may be arranged are more flexible, and more positions can be used for arrangement, so that the parasitic resistance and capacitance can be further reduced, thereby improving the light emission uniformity.

In the embodiment of the present disclosure, the arrangement of the plurality of drive ends on a column of electrode units 307 is realized by using solder balls. In other embodiments, the conductive element may further be realized by arranging a contact plug in the insulating layer to electrically connect the electrode unit 307 to the drive circuit.

As shown in FIG. 9, the solder balls 310 are uniformly arranged in the direction of extension of the electrode unit 307, so as to ensure that each drive end has a similar signal transmission distance, thereby improving the uniformity of light emitting of the laser emitter.

In this embodiment, the electrode unit 307 is a column of strip-shaped electrodes, and a column of solder balls 310 is uniformly arranged.

It should be noted that, in the conventional technologies, the size of the solder ball 310 is relatively large. In order to avoid a short circuit between adjacent electrode units 307, in the embodiment of the present disclosure, the solder balls of the electrode units 307 are staggered with respect to each other in the direction of extension of the electrode unit 307. In this way, the distance between adjacent solder balls of the adjacent electrode units 307 can be increased, and the problem of the short circuit between adjacent solder balls can be reduced. In other embodiments, if the size of the interconnect structure for realizing the electrical connection between the drive circuit and the electrode unit by the drive end is relatively small, the interconnect structure may not be staggered with respect to each other in the direction of extension of the electrode unit 307.

It should be noted that, in the above embodiment, the laser emitter includes a substrate. The substrate is a part of the light-emitting stack, and the substrate is located on a side of the second reflector away from the active region, that is, the laser emitter is a back side illumination laser emitter. In other embodiments, the substrate may be further removed after the light-emitting unit is formed on the substrate. That is to say, the laser emitter may further not include the substrate.

It should be further noted that, for the embodiment with the microlens structure arranged, when the laser emitter does not include the substrate, it is only necessary to arrange the microlens structure on the light emission side of the laser emitter.

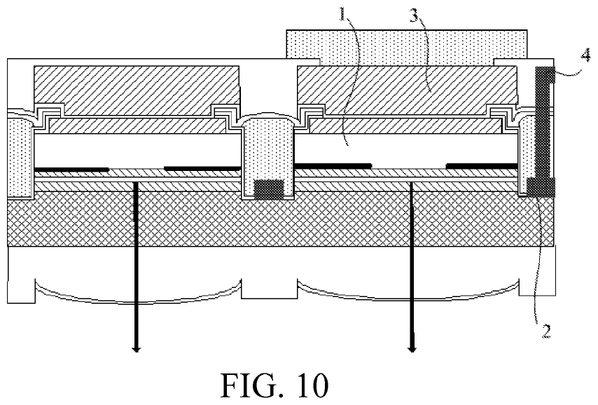

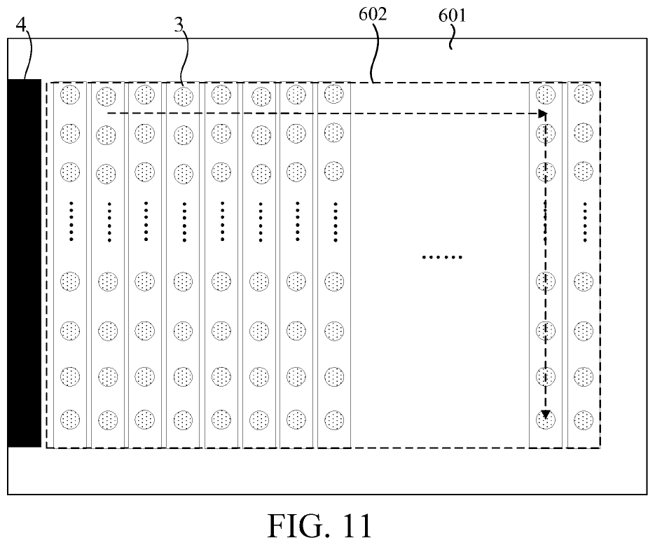

Referring to FIG. 10 and FIG. 11, FIG. 10 and FIG. 11 respectively show a side view and a top view of a laser emitter according to a third embodiment of the present disclosure. Similar to the first embodiment, the laser emitter in the embodiment of the present disclosure is a back side illumination laser emitter. The laser emitter includes a back side as a light emission surface and a front side opposite to the back side. The direction of light emitting A is from the front side to the back side of the laser emitter.

A first contact electrode 1 is an anode contact electrode, and is connected to a drive circuit through an electrode unit 3.

The electrode unit 3 is located on the front side of the laser emitter and is an anode interconnect metal layer of the laser emitter. As shown in FIG. 11, the electrode units 3 are a plurality of strip-shaped electrodes in a column and distributed in parallel in a light-emitting region 602 of the laser emitter.

The second contact electrode 2 is a cathode contact electrode, and is located on the back side of the laser emitter. A difference with the first embodiment is that in the embodiment of the present disclosure, the second contact electrode 2 is arranged on the second reflector and connected to the cathode interconnect metal layer 4 through an interconnect structure perpendicular to the direction of the light-emitting stack, and the cathode interconnect metal layer 4 is located on the front side of the laser emitter and in a peripheral region 601 around the light-emitting region 602.

In the embodiment of the present disclosure, the anode interconnect metal layer and the cathode interconnect metal layer 4 are both located on the front side of the laser emitter to form coplanar electrode. The drive circuit may be connected to the anode interconnect metal layer and the cathode interconnect metal layer 4 by using solder ball.

It should be noted that, in other embodiments, the first contact electrode 1 may alternatively be the cathode contact electrode, and the second contact electrode 2 may be the anode contact electrode, which are respectively configured to load drive signals with different electrical properties in the drive circuit.

It should be noted that, in this embodiment, the first contact electrode and the second contact electrode are coplanar electrode, and the laser emitter may include an N-doped substrate or an undoped substrate. The substrate is manufactured into a microlens structure. In other embodiments, the laser emitter may not include the substrate. Specifically, after the light-emitting stack is formed, the substrate is removed.

In this embodiment, the second contact electrodes 2 of a plurality of light-emitting points in the laser emitter are connected together, and the cathode interconnect metal layer 4 is a rectangular structure. Specifically, the cathode interconnect metal layer 4 herein is a rectangle arranged on a side of the light-emitting region. In other embodiments, the cathode interconnect metal layer may further be an annular structure, an elliptical structure, a runway-shaped structure, and the like around the light-emitting region.

It should be noted that, the arrangement of the light-emitting points of the laser emitter of the present disclosure is not limited to the matrix array arrangement shown in FIG. 7, FIG. 9, or FIG. 11, and may further be other regular arrangement modes, such as the staggered arrangement shown in FIG. 5. The electrode unit is not limited to the rectangle shown in FIG. 7, FIG. 9, or FIG. 11. For example, the light-emitting points in a staggered arrangement are shown in FIG. 5, and one light-emitting unit may be a plurality of light-emitting points regularly arranged in a direction of extension. In addition, the shape of the electrode unit may be set according to the arrangement position of the light-emitting points, such as a curved edge shape shown in FIG. 5.

In order to resolve the technical problem, an embodiment of the present disclosure further provides a light source assembly, including a laser emitter and a driving board.

The laser emitter is the laser emitter in the embodiment of the present disclosure. For the technical details, reference is made to the related description of the foregoing embodiment.

The driving board includes: a drive circuit, configured to provide a drive signal; and a first bonding pad, configured to be electrically connected to the electrode unit and provide the drive signal to the electrode unit. The emitted light formed by the light source assembly of the present disclosure has relatively high uniformity.

In addition, the driving board further includes a second bonding pad, configured to provide signals with different electrical properties to the laser emitter.

The driving board may be an integrated circuit (IC) chip or a printed circuit board (PCB). The IC chip or the PCB is provided with a first bonding pad and a second bonding pad with different electrical properties, which are respectively electrically connected to interconnect metal with the corresponding electrical properties of the laser emitter through conductive elements. The drive circuit includes a driving switch that controls on/off of the drive signal. When the driving switch is turned on, the drive signal is injected into the laser emitter to control the laser emitter to emit light. When the driving switch is turned off, the laser emitter stops emitting light. In the IC chip, the driving switch may be a MOS switch, such as a PMOS or an NMOS. In the PCB, the driving switch may be a GaN switch.

In a specific embodiment, the IC chip is used as the driving board, and the MOS switch is configured to control the laser emitter to emit light. The MOS switch integrated on the IC chip is usually a structure with a large length-width ratio. For the embodiment of the present disclosure with solder balls as the conductive elements, the direction of extension of the MOS switching transistor may be caused to be consistent with the direction of extension of the electrode unit of the laser emitter, and a plurality of solder balls are electrically connected to the MOS switching transistor in the direction of extension, so that the drive signal of the MOS switching transistor is outputted from a plurality of drive ends, thereby reducing the loss caused by the transmission of the drive signal in the direction of extension of the MOS switching transistor.

Correspondingly, the present disclosure further provides a laser radar, including an emitting module and a receiving module. The emitting module includes the light source assembly provided in the embodiment of the present disclosure and is configured to transmit a detection beam. The receiving module includes one or more photodetectors, and is configured to receive an echo beam of the detection beam reflected by a target object and convert the echo beam to an electrical signal.

In the emitting module of the laser radar in the embodiment of the present disclosure, the light source assembly provides uniform emitted light, so that the detection accuracy of the laser radar can be improved.

Although the present disclosure is disclosed above, the present disclosure is not limited thereto. A person skilled in the art can make various changes and modifications without departing from the spirit and the scope of the present disclosure. Therefore, the protection scope of the present disclosure should be subject to the scope defined by the claims. Although the present disclosure is disclosed above, the present disclosure is not limited thereto. A person skilled in the art can make various changes and modifications without departing from the spirit and the scope of the present disclosure. Therefore, the protection scope of the present disclosure should be subject to the scope defined by the claims.

1. A laser emitter, comprising:
a light-emitting stack, comprising a first reflector, an active region, and a second reflector sequentially arranged in a light emission direction, wherein
the light-emitting stack comprises one or more light-emitting units, and each of the one or more light-emitting units comprises a plurality of light-emitting points being regularly arranged; and
an electrode located on a side of the first reflector away from the active region, wherein the electrode is corresponding to a light-emitting unit of the one or more light-emitting units and is configured to load a driving signal to the light-emitting unit.

2. The laser emitter of claim 1, wherein the electrode comprises two drive ends configured to load the driving signal to the light-emitting unit and
wherein the two drive ends are arranged at two ends of the electrode in an extension direction, and
the laser emitter further comprises two bonding pads, each of the two drive ends corresponding to one of the two bonding pads and configured to load the driving signal.

3. The laser emitter of claim 1, further comprising an insulating layer located on the side of the first reflector away from the active region, wherein the insulating layer is configured to cover the electrode and isolate adjacent electrodes.

4. The laser emitter of claim 3, wherein the electrode comprises a plurality of drive ends configured to load the driving signal to the light-emitting unit;
the laser emitter further comprises a plurality of solder balls;
the insulating layer comprises a plurality of openings, wherein a solder ball of the plurality of solder balls is corresponding to a drive end of the plurality of drive ends and an opening of the plurality of openings, and wherein the solder ball protrudes from a surface of the insulating layer through the opening, and the solder ball is configured to load the driving signal.

5. The laser emitter of claim 4, wherein the plurality of solder balls are uniformly arranged in the extension direction of the electrode.

6. The laser emitter of claim 4, wherein
solder balls of the adjacent electrodes are arranged in the extension direction of the adjacent electrodes in an interlacing manner.

7. The laser emitter of claim 1, wherein the light-emitting stack further comprises a substrate located on a side of the second reflector away from the active region; and
each of the plurality of the light-emitting points comprises:
a first contact electrode located on the side of the first reflector away from the active region; and
a second contact electrode located on a side of the substrate away from the active region.

8. The laser emitter of claim 7, wherein the second contact electrode comprises an aperture.

9. The laser emitter of claim 1, wherein each of the plurality of the light-emitting points comprises a first contact electrode located on the side of the first reflector away from the active region and a second contact electrode located on a side of the second reflector facing the active region.

10. The laser emitter of claim 7, wherein first contact electrodes of the light-emitting unit are connected to the electrode; and
second contact electrodes of the plurality of the light-emitting points are connected.

11. The laser emitter of claim 1, wherein the light-emitting stack comprises a microlens on a light emission surface.

12. The laser emitter of claim 1, wherein the laser emitter comprises a vertical-cavity surface-emitting laser, and the first reflector and the second reflector comprise distributed Bragg reflectors.

13. The laser emitter of claim 12, wherein the laser emitter is a back-side illumination laser emitter.

14. A light source, comprising a laser emitter of claim 1, and a driving board
wherein the driving board comprises a drive circuit configured to provide a driving signal, and a first bonding pad electrically connected to the electrode and configured to provide the driving signal to the electrode.

15. The light source of claim 14, wherein the driving board further comprises a second bonding pad configured to provide a signal of a different electrical polarity to the laser emitter.

16. The light source of claim 15, wherein the second bonding pad comprises an annular bonding pad surrounding the electrode.

17. A LiDAR, comprising a transmitter and a receiver, wherein
the transmitter comprises the light source of claim 14, and is configured to transmit a detection beam; and
the receiver comprises a photodetector and is configured to receive an echo beam of the detection beam reflected by a target object and convert the echo beam to an electrical signal.

18. The laser emitter of claim 9, wherein first contact electrodes of the light-emitting unit are connected to the electrode; and
second contact electrodes of the plurality of the light-emitting points are connected.
